(19) United States
(12) Patent Application Publication
(10) Pub. No.: US 2014/0070169 A1
(43) Pub. Date: Mar. 13, 2014

(54) Separated Carbon Nanotube-Based Active Matrix Organic Light-Emitting Diode Displays

(71) Applicants: Chongwu Zhou, Arcadia, CA (US); Jialu Zhang, Los Angeles, CA (US); Chuan Wang, East Lansing, MI (US); Yue Fu, Los Angeles, CA (US)

(72) Inventors: Chongwu Zhou, Arcadia, CA (US); Jialu Zhang, Los Angeles, CA (US); Chuan Wang, East Lansing, MI (US); Yue Fu, Los Angeles, CA (US)

(21) Appl. No.: 14/025,511

(22) Filed: Sep. 12, 2013

Related U.S. Application Data
(60) Provisional application No. 61/700,102, filed on Sep. 12, 2012.

(51) Int. Cl. H01L 27/32

(52) U.S. Cl. CPC H01L 27/3274; B82Y 15/00
USPC 257/29; 438/23; 977/938; 977/842

(57) ABSTRACT

A separated carbon nanotube-based active matrix organic light-emitting diode (AMOLED) device including a substrate and transistors. Each transistor includes an individual back gate patterned on the substrate and a gate dielectric layer disposed over the substrate. An active channel including a network of separated semiconducting nanotubes is disposed over a functionalized surface of the gate dielectric layer. A source contact and a drain contact are formed on two ends of the active channel, with the network of separated nanotubes between the source contact and the drain contact. An organic light-emitting diode (OLED) display device is coupled to the drain of one of the transistors. A system includes a display control circuit having a substrate, with scan lines, data lines, and AMOLED devices formed on the substrate, with each AMOLED device coupled to one of the scan lines and one of the data lines.

### CROSS-REFERENCE TO RELATED APPLICATION

This application claims priority under 35 U.S.C. §119(e) to U.S. Application Ser. No. 61/700,102 entitled “SEPARATED CARBON NANOTUBE-BASED ACTIVE MATRIX ORGANIC LIGHT-EMITTING DIODE DISPLAYS,” filed on Sep. 12, 2012, which is incorporated by reference herein in its entirety.

### STATEMENT OF GOVERNMENT INTEREST

This invention was made with government support under National Science Foundation Grant CCF-0702204 and under Defense Threat Reduction Agency Grant HDTRA1-10-1-0015. The government has certain rights in the invention.

### TECHNICAL FIELD

This invention is related to active matrix organic light-emitting diodes (AMOLEDs) having separated carbon nanotubes as well as displays including the same.

### BACKGROUND

Due at least in part to their high light efficiency, superior color purity, low power consumption, large view angle, excellent flexibility, and low temperature processing, organic light-emitting diodes (OLEDs) are promising candidates for the next generation display technologies. However, the fabrication of thin-film transistors (TFTs) in the active matrix (AM) backplane is still challenging. Unlike the requirement of driving transistors for traditional liquid crystal displays (LCDs), where amorphous silicon (a-Si) (mobility ˜1 cm²V⁻¹s⁻¹) is applied as the transistor channel material, higher current driving capability is needed. Although polycrystalline silicon (poly-Si) which has better mobility (˜150 cm²V⁻¹s⁻¹) is used as a temporary solution for AMOLED display transistors, its high cost, low transparency, high-temperature processing, short life time, and poor uniformity limits the commercial implementation of AMOLED displays. Other candidates such as organic semiconductor materials are also attractive, but similar to a-Si, they also suffer from low carrier mobilities.

### SUMMARY

Devices, systems, and methods are disclosed for implementing separated semiconducting nanotube-based active matrix organic light-emitting diode (AMOLED) displays.

In a first general aspect, a device includes a substrate and transistors. Each of the transistors includes an individual back gate patterned on the substrate. A gate dielectric layer is disposed over the substrate, and a surface of the gate dielectric layer is functionalized with linker molecules. Each transistor includes an active channel. The active channel includes a network of separated nanotubes disposed over the functionalized surface of the gate dielectric layer. The network of separated nanotubes includes separated semiconducting nanotubes. Each transistor includes a source contact and a drain contact formed on two ends of the active channel, with the network of separated nanotubes therebetween.

In a second general aspect, a system includes a display control circuit and an organic light-emitting diode (OLED) display device. The display control circuit includes a substrate and devices formed on the substrate. Scan lines and data lines are formed in the substrate. Each of the devices is coupled to a scan line and a data line. Each device includes transistors. Each of the transistors includes an individual back gate patterned on the substrate. A gate dielectric layer is disposed over the substrate, and a surface of the gate dielectric layer is functionalized with linker molecules. Each transistor includes an active channel including a network of separated nanotubes disposed over the functionalized surface of the gate dielectric layer. The network of separated nanotubes includes separated semiconducting nanotubes. Each of the transistors includes a source contact and a drain contact formed on two ends of the active channel with the network of separated nanotubes therebetween. The OLED display device includes OLED pixels, and each of the OLED pixels is coupled to a device of the display control circuit.

Implementations can optionally include one or more of the following features. The gate dielectric layer can include a first dielectric layer disposed over the substrate and a second dielectric layer disposed over the first dielectric layer. The second dielectric layer can have better adhesion with the linker molecules than the first dielectric layer. The first and second dielectric layers can be 40-nm Al₂O₃ and 5-nm SiO₂, respectively. The substrate can include SiO₂ or silicon. The back gate dielectric material can include SiO₂, Al₂O₃, or indium tin oxide (ITO). The surface of the gate dielectric layer can include SiO₂, and the linker molecules can include amine groups. The surface of the gate dielectric layer can be functionalized by aminopropyltriethoxy silane (APTES) in isopropanol alcohol (IPA) solution with an APTES:IPA volume ratio of 1:10. The surface can be deposited with an enriched separated semiconducting nanotube solution with a concentration of 98%.

In some cases, the active channel of each transistor has a length of 20 μm. The active channel can have a width of 100 μm. The active channel can have a density of 45 separated semiconducting nanotubes per μm². In certain cases, an on/off ratio of the device exceeds 10⁴.

The transistors include a first transistor and a second transistor. The gate of the first transistor is configured to receive a first voltage for controlling the first transistor. The source of the first transistor receives a signal. The drain of the first transistor is coupled to a gate of a second transistor. The source or the drain of the second transistor is configured to receive a second voltage. A current flowing across the second transistor can be associated with the signal and the second voltage. Each transistor can include a capacitor including first and second pins. The first pin can be coupled between the drain of the first transistor and the gate of the second transistor. The second pin can be coupled to the source of the second transistor. The capacitor can be configured to store and stabilize a voltage from the signal during a period.

In some cases, the device includes an OLED display device coupled to the drain of the second transistor. An output light intensity of the OLED device can be modulated by the signal. A modulation of the output light intensity can exceed 10⁵.

In certain cases, the OLED display device and the display control circuit are monolithically integrated on the substrate. The system can integrate, for example, 500 OLED pixels in the OLED display device and 1,000 transistors in the display control circuit for driving OLED pixels in the OLED display device.

In another aspect, transistors are formed on a substrate, and a capacitor is coupled to the transistors. Forming each transistor on the substrate includes patterning an individual back gate on the substrate, disposing a gate dielectric layer over the substrate, functionalizing a surface of the gate dielectric layer with linker molecules, disposing an active channel including a network of separated nanotubes over the functionalized surface of the gate dielectric layer, and forming a source contact and a drain contact on two ends of the active channel with the network of separated nanotubes therebetween. The network of separated nanotubes includes separated semiconducting nanotubes.

Implementations may include one or more of the following features. In one example, a SiO₂ layer is deposited on the gate dielectric layer to form a bilayer gate dielectric layer before functionalizing the surface of the gate dielectric layer. In some cases, the transistors include a first transistor and a second transistor, and coupling a capacitor to the transistors includes coupling a first pin of a capacitor between the drain of the first transistor and the gate of the second transistor, and coupling a second pin of the capacitor to the source contact of the second transistor. In certain cases, an organic light-emitting diode (OLED) display device is coupled to the drain contact of the second transistor.

In some implementations, the transistors include a first transistor and a second transistor, the gate of the first transistor is configured to receive a first voltage for controlling the first transistor, the source of the first transistor is configured to receive a signal, the drain of the first transistor is coupled to a gate of the second transistor, the source or the drain of the second transistor is configured to receive a second voltage, a current flowing across the second transistor is associated with the signal and the second voltage, and the capacitor is configured to store and stabilize a voltage from the signal during a period. In some instances, an organic light-emitting diode display device is coupled to the drain of the second transistor, and an output light intensity of the organic light-emitting diode display device is modulated by the signal.

The details of one or more disclosed implementations are set forth in the accompanying drawings and the description below. Other features, aspects, and advantages will become apparent from the description, the drawings, and the claims.

### BRIEF DESCRIPTION OF THE DRAWINGS

FIGS. 1A-1C depict an AMOLED circuit and layout. FIG. 1A depicts a schematic diagram for an AMOLED circuit. Each pixel contains one switching transistor, one driving transistor, one charge storage capacitor, and an OLED. FIG. 1B depicts a top view for the layout of a single pixel AMOLED with an area of 500×500 μm². FIG. 1C is a cross-sectional view for an AMOLED pixel including a glass substrate, patterned Ti/Au gate electrode, Al₂O₃ gate dielectric, separated carbon nanotube (CNT) thin film for the active channel, Ti/Pd source and drain contacts, integrated OLED (indium tin oxide (ITO)/N,N′-di-[(1-naphthyl)-N,N′-diphenyl]-1,1′-biphenyl)-4,4′-diamine (NPD)/tris(8-hydroxyquinolinato)aluminum (Alq₃)/LiF/Al), and a SiO₂ passivation layer.

FIGS. 2A-2C show field emission scanning electron microscopy (FE-SEM) images of separated CNT thin-films with different densities obtained by tuning the volume ratio of APTES and IPA used in the surface functionalization process. FIG. 2D shows a relationship between nanotube film density and APTES:IPA volume ratio. FIGS. 2E and 2F show channel length dependence of device on/off ratio and normalized on-current for transistors fabricated on nanotube films, respectively, using different APTES:IPA volume ratios.

FIG. 3A is a schematic diagram of a back-gated transistor built on separated nanotube thin-film with Ti/Au (5 Å/40 nm) back gate, Ti/Pd (5 Å/50 nm) contact electrodes, and Al₂O₃/SiO₂ bilayer gate dielectric (40 nm/5 nm). FIG. 3B is a FE-SEM image showing the channel of a back-gated SN-TFT with 20 μm channel length. FIGS. 3C and 3E show scanning electron microscope (SEM) images of separated nanotube thin-films deposited on Al₂O₃ and Al₂O₃/SiO₂ surface, respectively. FIGS. 3D and 3F show SEM images for the samples shown in FIGS. 3C and 3E, respectively, after one step of photolithography. FIG. 3G shows transfer (I_{D}-V_{G}) characteristics and gₘ-V_{G} characteristics of a typical SN-TFT (L=20 μm, W=100 μm) with V_{D}=1 V. FIG. 3H shows output (I_{D}-V_{D}) characteristics of the same device with V_{G} varying from −5 V to 5 V in 1 V steps as indicated by the arrow.

FIGS. 4A-4D are related to two-transistor single-pixel circuits. FIG. 4A shows an optical microscope image of the single pixel circuit with two SN-TFTs, one capacitor, and the ITO electrode for OLED integration. FIGS. 4B and 4C show transfer (I_{D}-V_{DATA}) characteristics of the single pixel circuit measured while V_{SCAN}=−5 V in linear scale (V_{DD}=1 V to 0.2 V with 0.2 V steps in the direction indicated by the arrow) and logarithm scale (V_{DD}=1 V), respectively. The inset in FIG. 4C shows a schematic diagram of the single pixel circuit. FIG. 4D shows output (I_{D}-V_{DD}) characteristics measured at V_{SCAN}=−5 V with different V_{DATA} (−5 V to 5 V with 1V steps in the direction indicated by the arrow).

FIG. 5 shows the current through an OLED (I_{OLED}) and OLED light intensity versus the voltage applied across the OLED (V_{OLED}) for a two-terminal measurement.

FIG. 6A shows characteristics of the OLED controlled by single pixel circuit, where the current flow through the OLED (I_{OLED}) is measured by sweeping the V_{DD}. The curves correspond to values of V_{DATA} from −5 to 5 V in 1 V steps in the direction indicated by the arrow. FIG. 6B shows plots of current through the OLED (I_{OLED}) and OLED light intensity versus V_{DATA} with V_{DD}=8 V.

FIG. 7A shows an image of an AMOLED substrate containing 7 AMOLED elements, each with 20×25 pixels. FIG. 7B is a photograph showing the pixels on an integrated AMOLED are turned on when V_{DATA}=−5 V, V_{SCAN}=−5V, and V_{DD}=8 V are applied for the pixels.

### DETAILED DESCRIPTION

Compared with other channel materials, one-dimensional nanoscale materials such as semiconductor nanowires (NWs) and single-walled carbon nanotubes (SWNTs) have advantages in terms of mobility, transparency, flexibility, and low temperature processing. AMOLED displays using NWs as the active channel materials. The device uniformity, reliability, and processing scalability can be improved by using pre-separated semiconducting nanotubes produced by density-gradient ultracentrifuge separation methods to yield transistors that exhibit highly uniform electrical performance. The use of high purity semiconducting nanotubes (referred to herein as “separated nanotubes,” “separated carbon nanotubes,” “separated semiconducting nanotubes,” and the like) allows a high on/off ratio (>10⁵), as well as excellent on-current density (˜1 μA/μm), which makes such separated carbon nanotube thin-film transistors (SN-TFTs) very attractive for AMOLED display applications.

AMOLED displays driven by SN-TFTs demonstrate high light efficiency, flexibility, lightweight, and low-temperature processing. The high mobility, high percentage of semiconducting nanotubes, and room-temperature processing compatibility of these SN-TFTs allow large-scale high-yield fabrication of devices with superior performance, carbon nanotube film density optimization, bilayer gate dielectric for improved substrate adhesion to the deposited nanotube film, and monolithically integrated AMOLED display elements with 500 pixels driven by 1,000 SN-TFTs. AMOLED displays described herein can be used in nanotube-based thin-film display electronics.

A monolithically integrated AMOLED display with SN-TFT based control circuit is described, and carbon nanotube film density is optimized with respect to transistor electrical performance. In addition, the single pixel control circuits including two SN-TFTs and one capacitor are made, and their OLED control capability is demonstrated. AMOLED display elements with 20×25 pixels driven by 1,000 SN-TFTs are fabricated and tested. Compared with conventional platforms, the SN-TFT platform shows advantages such as low temperature processing compatibility, scalability, reproducibility and device performance, and provides a practical and realistic approach for carbon nanotube based AMOLED display applications.

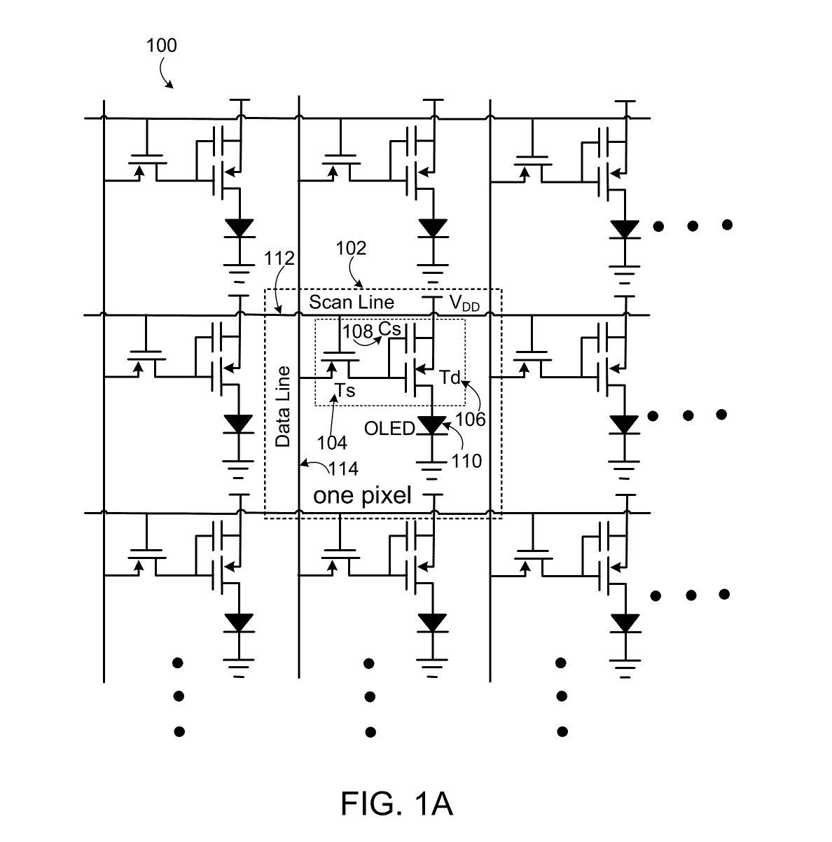

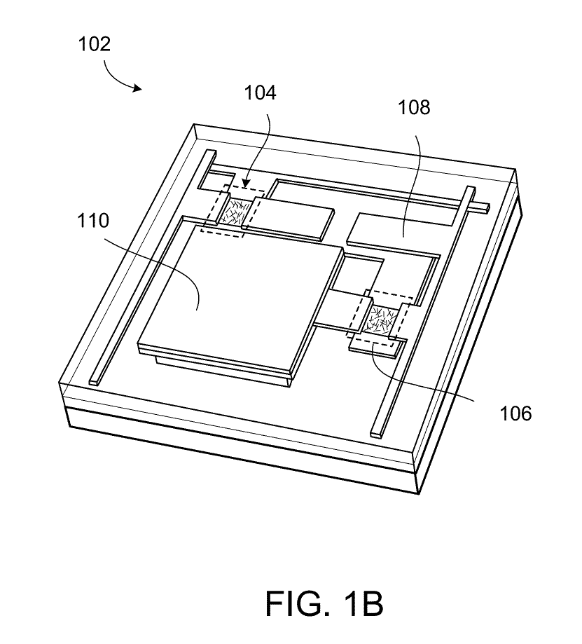

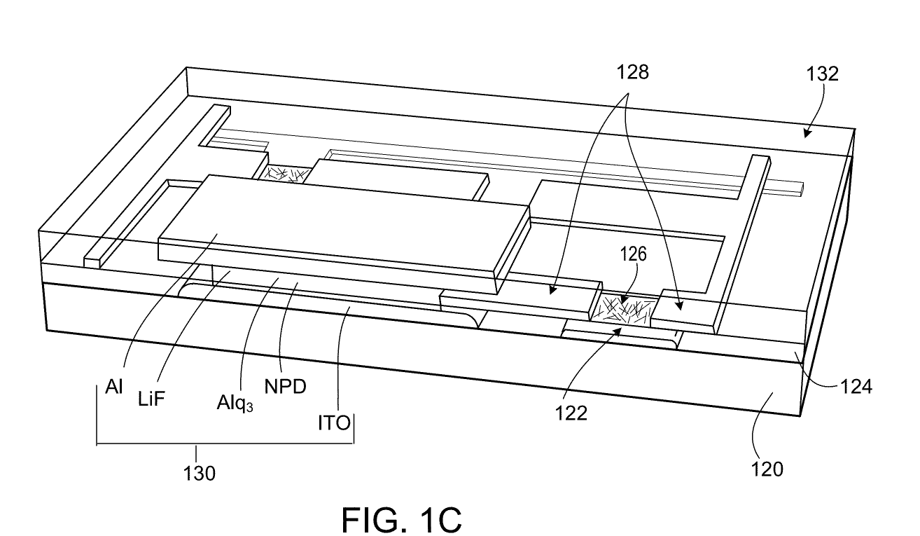

FIG. 1A depicts a schematic diagram of AMOLED circuit 100 with pixels 102. Each pixel 102 contains one switching transistor (Ts) 104, one driving transistor (Td) 106, one charge storage capacitor (Cs) 108, and one OLED 110. The switching transistor 104, controlled by a signal from a scan line 112, is employed to select one specific row of pixels in an AMOLED display element by passing the signal from a data line 114 through the channel of the switching transistor 104 to the gate of the driving transistor 106. The driving transistor 106 further controls the output light intensity of the OLED pixel 110 by modulating the current flowing through OLED. The capacitor Cs 108 is used to store and stabilize the voltage obtained from the data line 114 during one scanning period for line-by-line scanning technique typically used for dynamic displays.

Based on the circuit diagram, the corresponding layout of one pixel is shown in FIG. 1B (top view) and FIG. 1C (cross-sectional view). The single pixel layout has a total area of 500×500 μm² with OLED area of 200×200 μm², and is designed to be fabricated on glass substrate 120 with patterned Ti/Au (5 Å/40 nm) gate electrode 122, Al₂O₃ (40 nm) gate dielectric 124, separated nanotube thin-film for the active channel 126, Ti/Pd (5 Å/50 nm) source contacts and drain contacts 128, integrated green OLED 130, and a 200 nm SiO₂ passivation layer 132. The total fabrication consists of 7 photo masks and 15 fabrication steps.

To control the OLED intensity, the transistors in the control circuits have high current on/off ratio and excellent current drive capability. Shorter channel length and higher nanotube channel network density are understood to lead to high on-current density, which is needed for OLED display applications. However, it will also create more metallic nanotube pass in the channel, which may negatively affect the transistor current on/off ratio. Therefore, optimized device geometry and channel nanotube network density is understood to be a factor in OLED control.

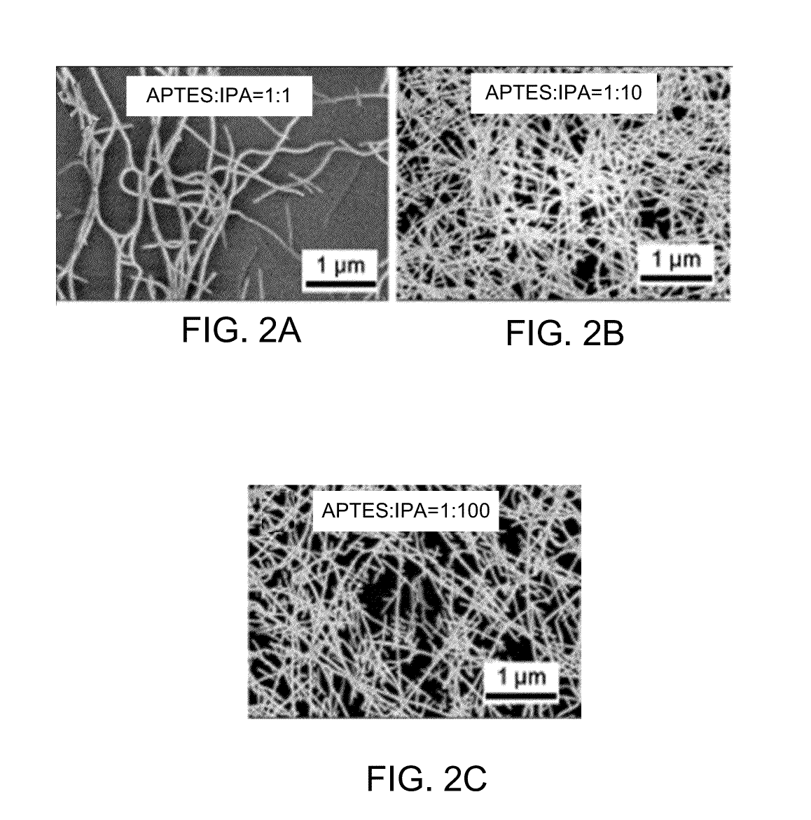

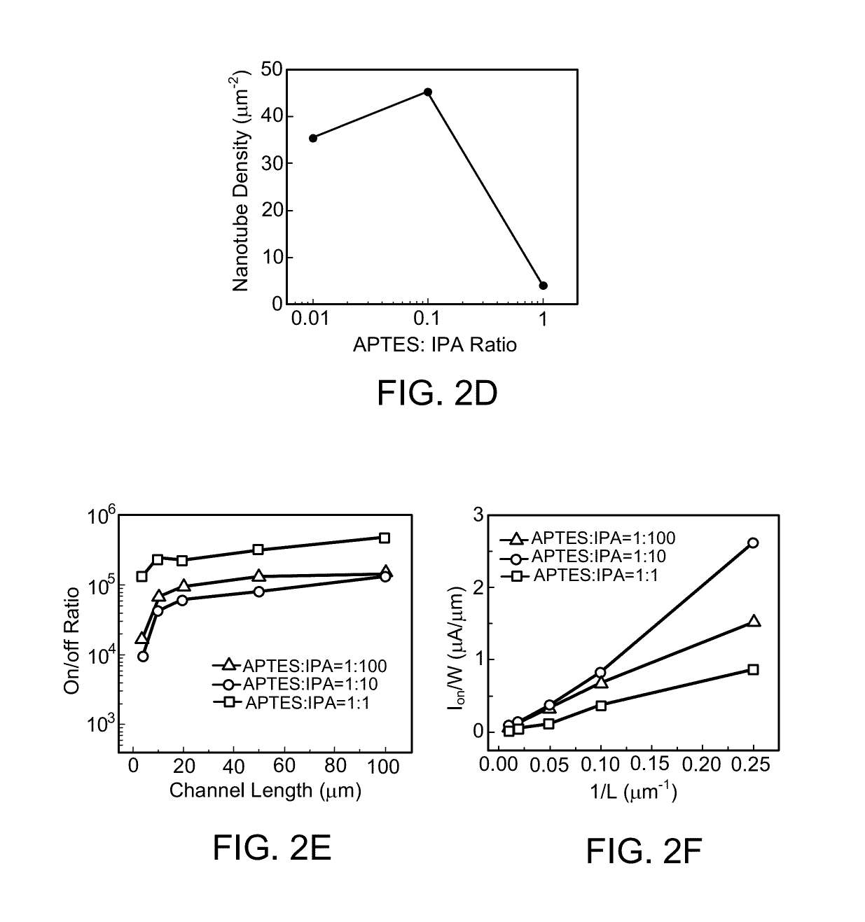

98% semiconducting carbon nanotube solution (from Nanointegris, Inc. Batch No. S08-665) is used, and uniform separated nanotube thin-film is achieved on a Si/SiO₂ surface by a solution-based aminopropyltriethoxy silane (APTES)-assisted separated nanotube deposition technique known in the art. The nanotube network density can be controlled by tuning the concentration of APTES in isopropanol alcohol (IPA) used for SiO₂ surface treatment before nanotube deposition. Three different conditions are studied (APTES:IPA=1:1, 1:10, 1:100), and the FE-SEM images of the resulting nanotube thin-film are shown in FIGS. 2A-2C, respectively. From the images, the nanotube density is found to vary when different volume ratios of APTES and IPA are used. From FIG. 2D, the sample with an APTES:IPA ratio of 1:1 has low nanotube network density (4 tubes/μm²) and the uniformity of the thin-film is poor. For the sample with an APTES:IPA ratio of 1:10, a highly uniform film is obtained with a density of 45 tubes/μm². If the solution is further diluted to APTES:IPA=1:100, the resulting film density decreases to 36 tubes/μm².

The relationship between nanotube film density and APTES:IPA ratio can be understood as follows: the effect of APTES is to functionalize the SiO₂ surface and form an amine-terminated monolayer, which can attract the nanotubes in solution to the substrate and form a uniform thin-film. When the APTES concentration is very high, instead of a uniform monolayer, multiple layers of APTES molecules are stacked onto the SiO₂ surface, leading to an uneven, low density nanotube film. As the APTES concentration in IPA is diluted, uniform monolayer APTES molecules are formed, which yields a highly uniform nanotube film with excellent density. However, when the APTES solution is diluted even further, the APTES monolayer may have defects and vacancies, so the nanotube film density may decrease again. Overall, by tuning the concentration of APTES in IPA, separated nanotube thin-film with different densities can be achieved.

Subsequently, electrical performance of the nanotube network with different density was investigated. 100 transistors with different channel geometry were fabricated on each sample with different nanotube density, and the channel length dependence of device on/off ratio and normalized on-current are shown in FIGS. 2E and 2F, respectively. From these two plots, it is seen that, with the benefit of high purity semiconducting nanotubes, all the devices with channel lengths larger than 20 μm have on/off ratios higher than 10⁴, and transistors made with nanotube film deposited using an APTES:IPA volume ratio of 1:10, which gives the highest nanotube density, also offer good current driving capability (0.5 μA/μm for 20 μm channel length devices). Based on the electrical performance, APTES:IPA volume ratio of 1:10 and device geometry of L=20 μm, W=100 μm are chosen as optimized conditions for transistors used in AMOLED control circuits.

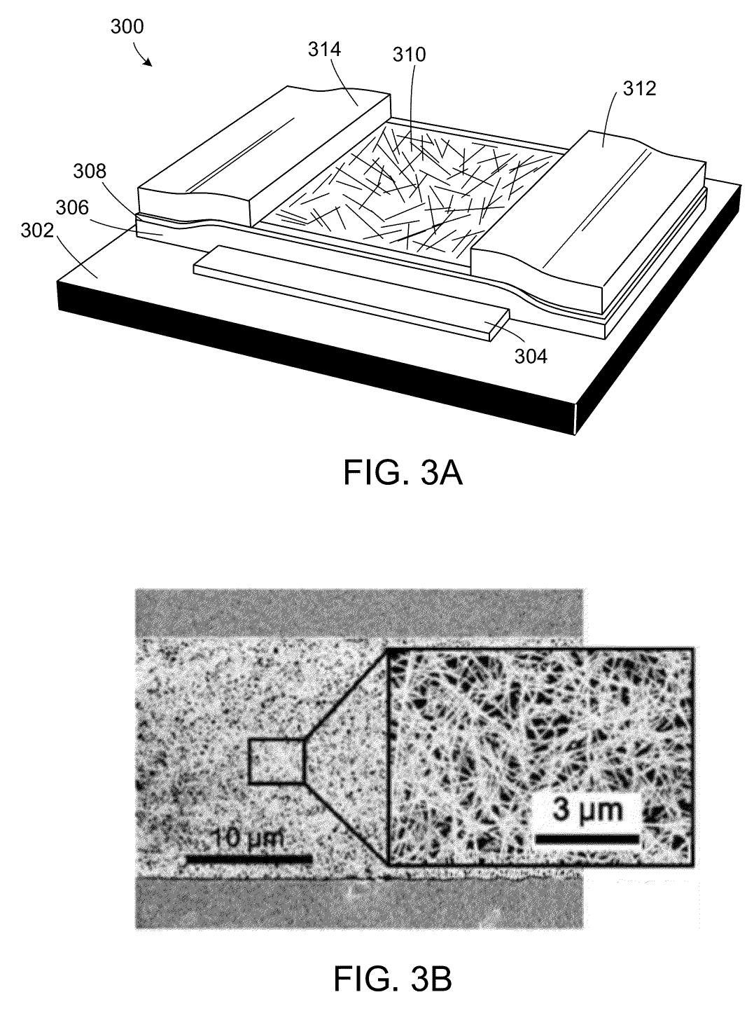

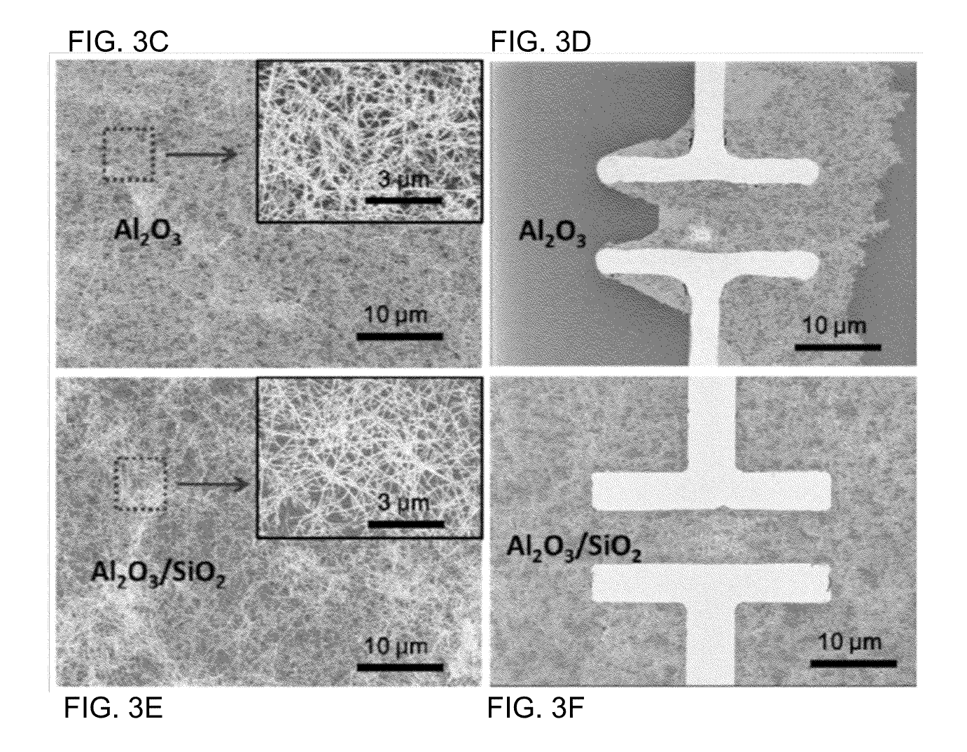

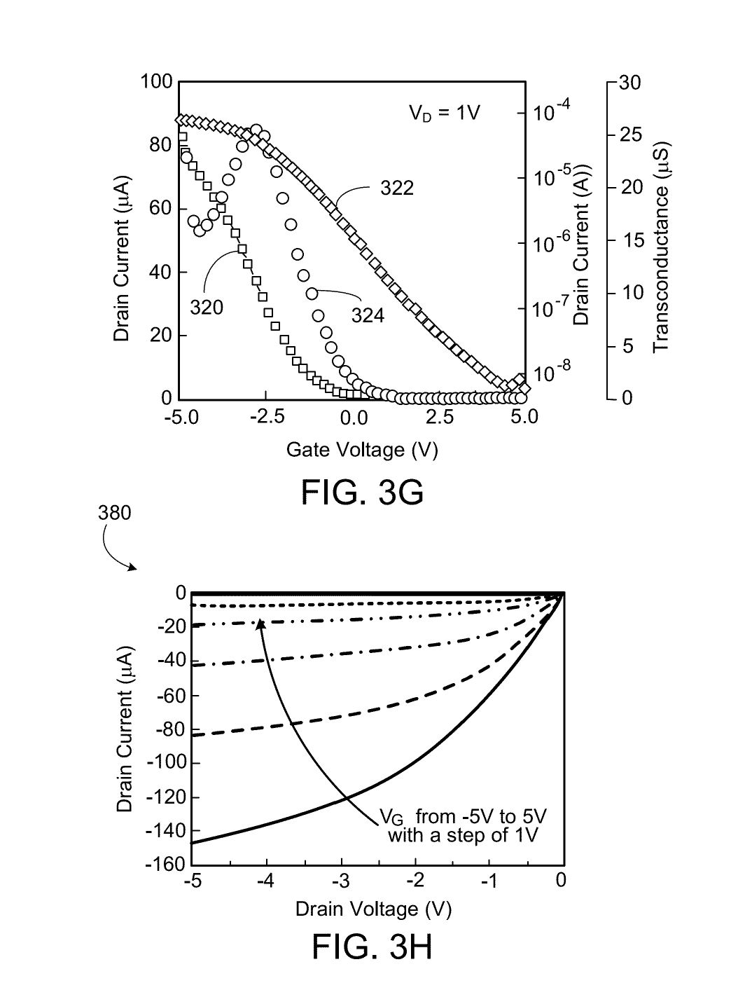

FIGS. 3A-3H show structure and electrical characteristics of the nanotube transistors used in the AMOLED. For the sake of a two transistor control circuit, individual back-gated device structure 300 is chosen as illustrated in FIG. 3A. 5 Å Ti and 40 nm Au are patterned on substrate 302 as the back gate 304, and 40 nm Al₂O₃ is deposited by atomic layer deposition (ALD) as the gate dielectric 306. In some examples, due at least in part to poor adhesion between Al₂O₃ and APTES molecules, the deposited nanotube thin-film on Al₂O₃ surface can peel off during the ensuing fabrication steps.

To improve the adhesion, a thin layer of SiO₂ (5 nm) 308 can be deposited on top of the Al₂O₃ layer 306 using an electron beam evaporator to form a bilayer gate dielectric. With the help of the SiO₂ buffer layer, a uniform nanotube thin film 310 is achieved, as shown in FIG. 3B. After the separated nanotube thin-film deposition, Ti/Pd (5 Å/50 nm) is applied on top of the channel network to form ohmic source and drain contacts 312 and 314. Subsequently, the nanotubes outside the channel region can be etched away by photolithography and oxygen plasma.

FIGS. 3C and 3E show SEM images of the separated nanotube thin-films deposited on Al₂O₃ and Al₂O₃/SiO₂ surfaces, respectively. FIGS. 3D and 3F show SEM images corresponding to the samples shown in FIGS. 3C and 3E, respectively, after one step of photolithography. FIG. 3D shows that nanotubes on the Al₂O₃ sample peeled off while, while FIG. 3F show that nanotubes on the Al₂O₃/SiO₂ bilayer dielectric still stick to the surface.

Electrical properties of a typical transistor are plotted in FIG. 3G, which contains transfer (I_{D}-V_{G}) characteristics (plot 320 for linear scale and plot 322 for log scale) and gₘ-V_{G} characteristics (plot 324) measured with V_{D}=1 V. The on-current at V_{D}=1 V and V_{G}=−5 V is 82.9 μA, corresponding to a current density of 0.829 μA/μm. The on/off ratio exceeds 10⁴ and the peak transconductance is 25.5 μS. Based at least in part on the transconductance, the device mobility is extracted to be 31.65 cm²V⁻¹s⁻¹. A parallel plate model is used to estimate the gate capacitance when calculating the device mobility due to the complexity of the bilayer gate dielectric structure. If the electrostatic coupling between nanotubes is taken into consideration, the gate capacitance will be smaller and therefore the real mobility can be larger than the value listed here. FIG. 3H shows the output (I_{D}-V_{D}) characteristics of the same device measured with V_{G} varying from −5 V to 5 V in 1 V steps, which indicates nice field-effect operation and ohmic contacts.

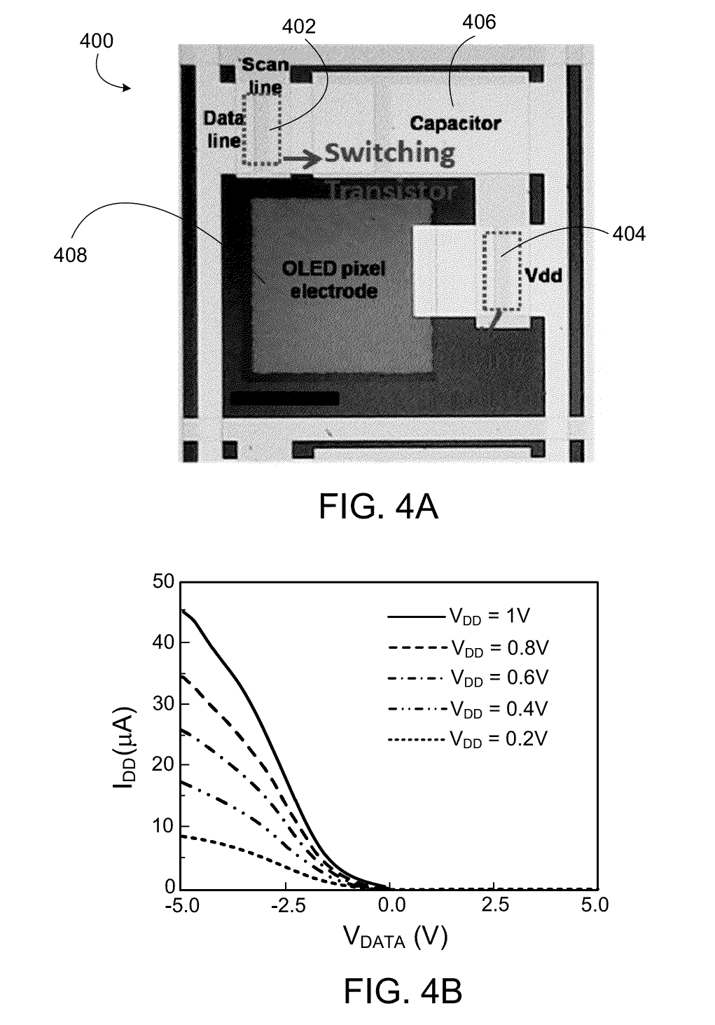

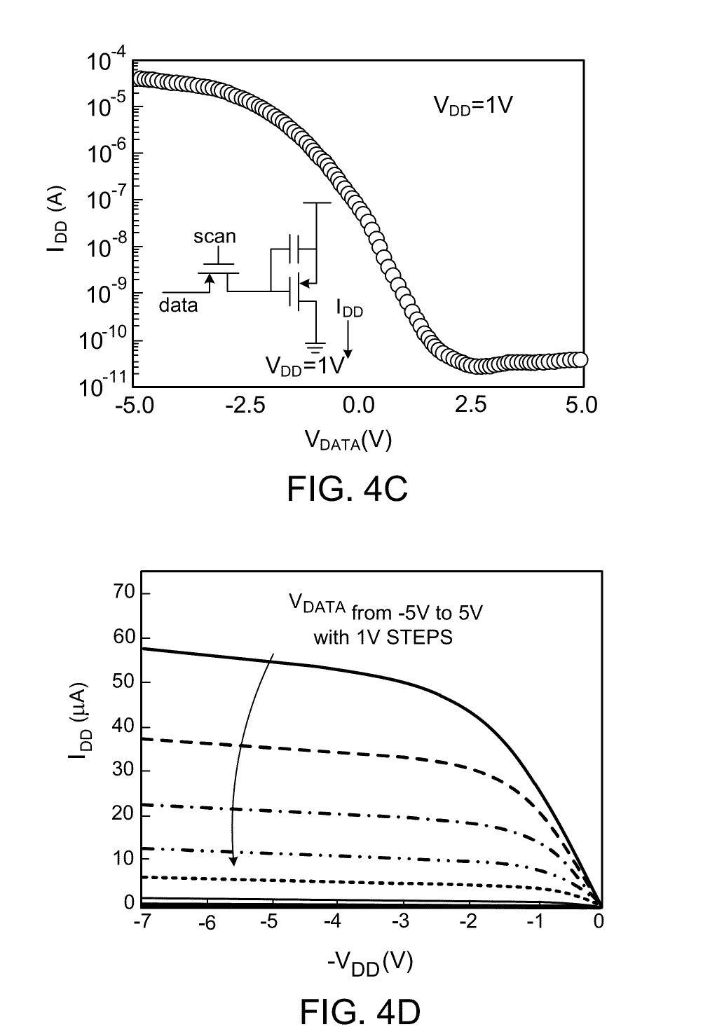

Following the single transistor analysis, the AMOLED pixel control circuits were fabricated and studied. FIG. 4A shows an optical microscope image of the fabricated single pixel circuit 400 before OLED, which contains two SN-TFTs as a switching transistor 402 and a driving transistor 404, one capacitor 406, and one indium-tin oxide (ITO) electrode 408 for OLED integration.

To operate the driving transistor, −5 V was applied to a scan line to turn on the switching transistor. Transfer (I_{D}-V_{DATA}) characteristics and are plotted in FIGS. 4B and 4C in linear scale and logarithm scale, respectively. The various curves in FIG. 4B correspond to various values of the supply voltage V_{DD} (0.2 V to 1 V with 0.2 V steps), which is connected to the source of the driving transistor as shown in the inset schematic diagram in FIG. 4C. From the transfer characteristics in logarithm scale, the two-transistor circuits are seen to exhibit an excellent on/off ratio (higher than 10⁶), which resulted at least part from the optimized channel geometry and film density as well as the high semiconducting nanotube purity. This on/off ratio is crucial in order to guarantee that the control circuits can fully turn off the OLED pixels.

Besides the on/off ratio, the current-drive of the circuit is also important for AMOLED displays, which is examined by the output (I_{D}-V_{DD}) characteristics shown in FIG. 4D. To keep the V_{GS} value of the driving transistor constant, the source of the driving transistor is grounded while the drain terminal (−V_{DD}) is swept from 0 V to −7 V, and different curves are obtained with V_{DATA} changing from −5 V to 5 V with 1 V steps. From this figure, current flow through the driving transistor is seen to saturate under high V_{DD}, and with the optimized semiconducting nanotube density, 50 μA is achieved when V_{DD}=3 V, V_{DATA}=−5 V, and V_{SCAN}=−5 V, which offers high enough current density to drive OLED pixels with a designed area of 200×200 μm².

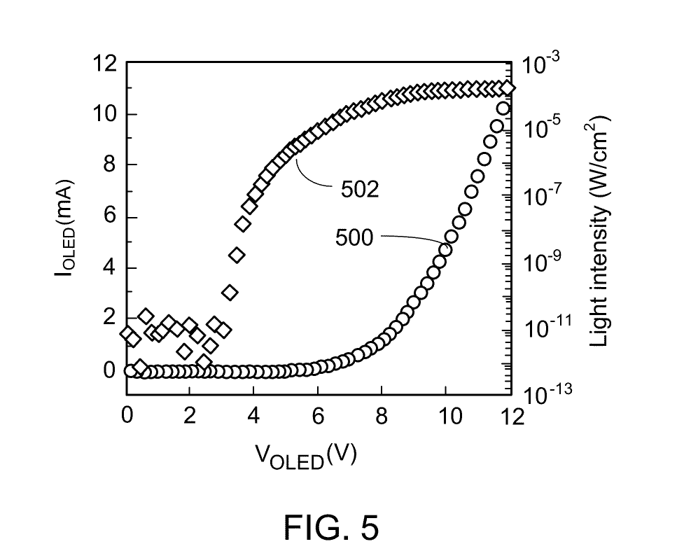

To further understand the behavior of the circuit controlled AMOLED, an OLED was connected to and controlled by a single pixel control circuit using wire bonding. Standard NPD/Alq₃ OLED with multi-layered configuration was employed, with ITO/4-4′-bis[N-(1-naphthyl)-N-phenyl-amino]bi-phenyl (NPD) [40 nm]/tris(8-hydroxyquinoline) aluminium (Alq₃) [40 nm]/LiF [1 nm]/aluminum (Al) [100 nm], whose transfer characteristics are described herein with respect to FIG. 5. FIG. 5 shows two terminal measurement of the OLED showing the current through the OLED (I_{OLED}) (plot 500) and OLED light intensity (plot 502) versus the voltage applied across the OLED (V_{OLED}).

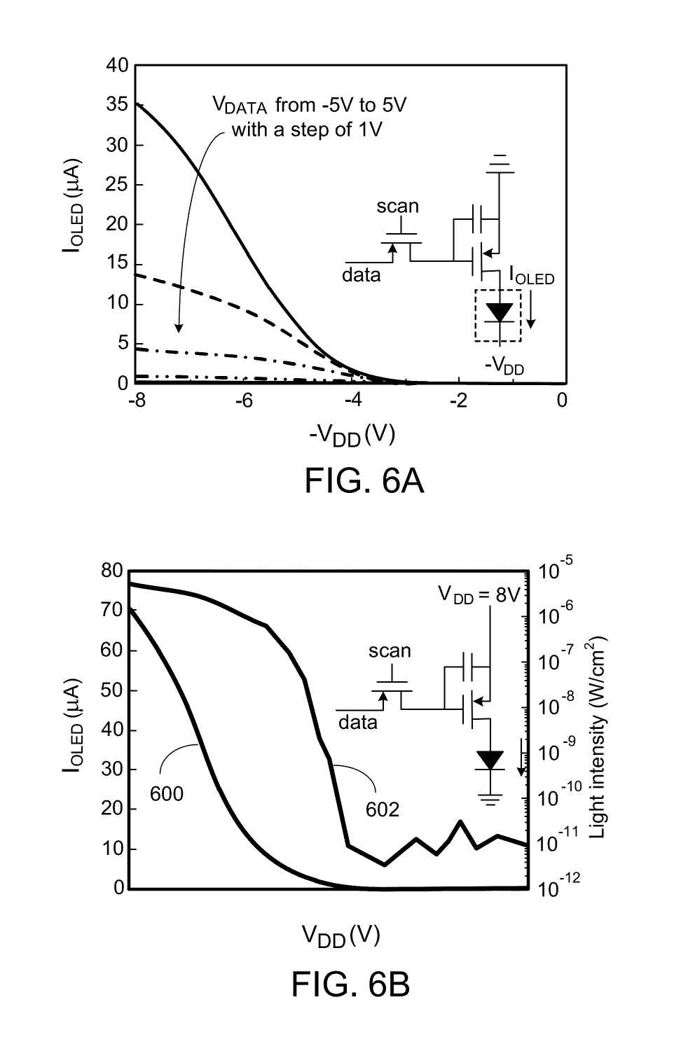

The schematic of the OLED control circuit is shown in the inset of FIG. 6A, where the drain of the driving transistor is connected to an external OLED and a negative voltage (−V_{DD}) is applied to the cathode of the OLED. The current flow through the OLED (I_{OLED}) is measured by sweeping the V_{DD} while also changing input voltage V_{DATA} as plotted in FIG. 6A. V_{SCAN} is held at −5 V to keep the switching transistor on, and the family of curves correspond to various values of V_{DATA} from −5 to 5 V in 1 V steps. FIG. 6A illustrates that if V_{DATA} is sufficiently negative, the OLED will be turned on when the supply voltage is higher than the threshold voltage of the OLED (about 3 V), and the current flow through OLED will increase as V_{DATA} decreases. Therefore, the light intensity of the OLED can be modulated by V_{DATA}, which is directly revealed in FIG. 6B where current and output light intensity versus V_{DATA} characteristics (plots 600 and 60) with a fixed V_{DD} of 8 V as shown in the inset schematic. From FIG. 6B, it can be seen that when sweeping V_{DATA} from −5 V to 5 V, the current through OLED changes from 71 μA to 3.7 nA and the output light intensity also varies from 5.3×10⁻⁶ W/cm² to about 8×10⁻¹² W/cm², which exceeds 5 orders of magnitude difference. The significant change in the light intensity can be visually seen when the OLED is under various V_{DATA} voltages of −5, −3, −1, 1, 3, and 5 V, respectively, demonstrating that the external OLED can be fully turned on and turned off by changing the voltage of V_{DATA}.

Based on the discussion herein, a monolithically integrated AMOLED display element was fabricated. First, an array of AMOLED control circuit with 20×25 pixels driven by 1,000 SN-TFTs was fabricated using the same layout design as discussed herein. After that, 200 nm SiO₂ was deposited by electron beam evaporator as a passivation layer, leaving only the pre-patterned ITO electrodes open for OLED integration. Finally, green OLEDs with the same multilayer structure and thickness (ITO/NPD/Alq₃/LiF/Al) as used for the single pixel circuit were deposited by thermal evaporator onto ITO electrodes.

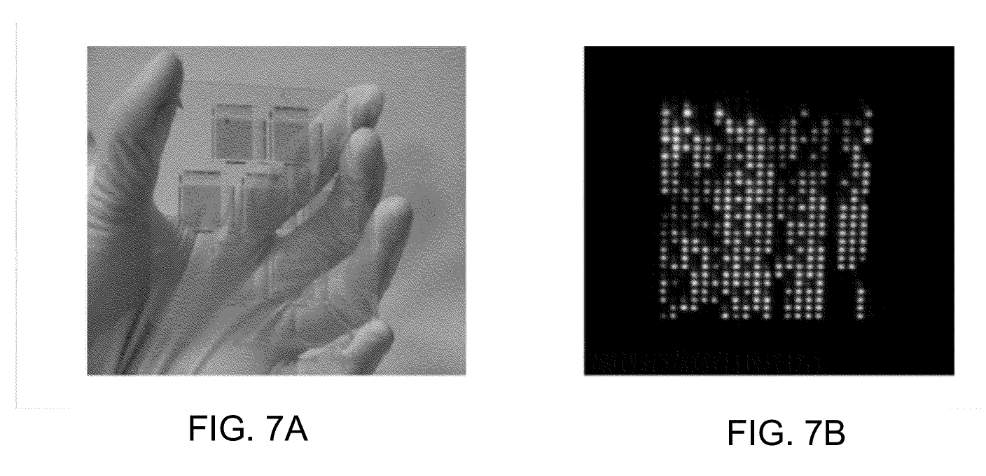

An optical image of a completed AMOLED substrate, which contains 7 AMOLED elements (20×25 pixels each) is shown in FIG. 7A. FIG. 7B is a photograph showing that all the pixels on one integrated AMOLED element are turned on when V_{DATA}=−5 V, V_{SCAN}=−5V, and V_{DD}=8 V are applied for all the pixels. In FIG. 7B, 348 out of 500 pixels are turned on, corresponding to a yield of 70%, which is acceptable for the demonstration purpose in the present laboratory-scale experiments. In some cases, the failed pixels are due to the top SiO₂ surface roughness, which can lead to short circuits during OLED evaporation, and can be improved by using an alternative passivation technique. This AMOLED display is understood to be driven solely by SN-TFT circuits.

In summary, by tuning the concentration of APTES in IPA solution during surface functionalization step, an optimized separated nanotube thin-film density of 45 tubes/μm² is achieved when 1:10 volume ratio between APTES and IPA is used. Based on the optimized nanotube density and device geometry, individual back-gated transistors with superior on/off ratio (>10⁴) and excellent current driving capability (˜0.8 μA/μm) have been fabricated with 10 μm channel length and 100 μm channel width. In addition, the electrical properties and OLED control capability of the single pixel AMOLED control circuit were examined and analyzed, and the modulation in the output light intensity was shown to exceed 10⁵. Moreover, a monolithically integrated AMOLED display element with 500 OLED pixels and 1,000 transistors was further demonstrated.

Further modifications and alternative embodiments of various aspects will be apparent to those skilled in the art in view of this description. Accordingly, this description is to be construed as illustrative only. It is to be understood that the forms shown and described herein are to be taken as examples of embodiments. Elements and materials may be substituted for those illustrated and described herein, parts and processes may be reversed, and certain features may be utilized independently, all as would be apparent to one skilled in the art after having the benefit of this description.

What is claimed is:

1. A device comprising:
a substrate; and
transistors, each of the transistors comprising:
an individual back gate patterned on the substrate;
a gate dielectric layer disposed over the substrate, a surface of the gate dielectric layer being functionalized with linker molecules;
an active channel comprising a network of separated nanotubes disposed over the functionalized surface of the gate dielectric layer, wherein the network of separated nanotubes comprises separated semiconducting nanotubes; and
a source contact and a drain contact formed on two ends of the active channel with the network of separated nanotubes therebetween.

2. The device of claim 1, wherein the gate dielectric layer comprises a first dielectric layer disposed over the substrate and a second dielectric layer disposed over the first dielectric layer, and the second dielectric layer has better adhesion with the linker molecules than the first dielectric layer.

3. The device of claim 1, wherein the surface of the gate dielectric layer comprises SiO₂ and the linker molecules comprise amine groups.

4. The device of claim 3, wherein the surface of the gate dielectric layer is functionalized by aminopropyltriethoxy silane (APTES) in isopropanol alcohol (IPA) with an APTES:IPA volume ratio of 1:10, and then deposited with an enriched separated semiconducting nanotube solution with a concentration of 98%.

5. The device of claim 1, wherein the active channel has a length of 20 μm, a width of 100 μm, and a density of 45 separated semiconducting nanotubes per μm².

6. The device of claim 1, wherein an on/off ratio of the device exceeds 10⁴.

7. The device of claim 1, wherein the transistors comprise a first transistor and a second transistor, and wherein:
the gate of the first transistor is configured to receive a first voltage for controlling the first transistor;
the source of the first transistor is configured to receive a signal; and
the drain of the first transistor is coupled to the gate of the second transistor,
the source or the drain of the second transistor is configured to receive a second voltage,
a current flowing across the second transistor is associated with the signal and the second voltage,
each of the transistors comprises a capacitor including first and second pins, the first pin being coupled between the drain of the first transistor and the gate of the second transistor and the second pin being coupled to the source of the second transistor, and
the capacitor is configured to store and stabilize a voltage from the signal during a period.

8. The device of claim 7, further comprising an organic light-emitting diode display device coupled to the drain of the second transistor, and wherein an output light intensity of the organic light-emitting diode display device is modulated by the signal.

9. The device of claim 8, wherein a modulation of the output light intensity exceeds 10⁵.

10. A system comprising:
a display control circuit comprising:
a substrate;
scan lines formed on the substrate;
data lines formed on the substrate; and
devices formed on the substrate, each device being coupled to one of the scan lines and one of the data lines and each device comprising:
transistors, each transistor comprising:
an individual back gate patterned on the substrate;
a gate dielectric layer disposed over the substrate, a surface of the gate dielectric layer being functionalized with linker molecules;
an active channel comprising a network of separated nanotubes disposed over the functionalized surface of the gate dielectric layer, wherein the network of separated nanotubes comprises separated semiconducting nanotubes; and
a source contact and a drain contact formed on two ends of the active channel with the network of separated nanotubes therebetween; and
an organic light-emitting diode (OLED) display device comprising OLED pixels, each OLED pixel being coupled to one of the devices of the display control circuit.

11. The system of claim 10, wherein the OLED display device and the display control circuit are monolithically integrated on the substrate.

12. The system of claim 10, wherein the system integrates 500 OLED pixels in the OLED display device and 1,000 transistors in the display control circuit for driving the OLED pixels.

13. The system of claim 10, wherein:
for each of the devices, the transistors include a first transistor and a second transistor, wherein:
the gate of the first transistor receives, from one of the scan lines, a first voltage for controlling the first transistor,
the source of the first transistor receives, from one of the data lines, a signal, and
the drain of the first transistor is coupled to a gate of the second transistor,
the source or the drain of the second transistor receives a second voltage,
a current flowing across the second transistor is associated with the signal and the second voltage, and
each of the devices comprises a capacitor comprising first and second pins, the first pin being coupled between the drain of the first transistor and the gate of the second transistor and the second pin being coupled to the source of the second transistor, the capacitor being configured to store and stabilize a voltage from the signal during a scanning period.

14. The system of claim 13, wherein the drain of the second transistor is coupled to one of the OLED pixels, and an output light intensity of the OLED pixel is modulated by the signal.

15. A method comprising:
forming transistors on a substrate,
wherein forming each of the transistors comprises:
patterning an individual back gate on the substrate,
disposing a gate dielectric layer over the substrate,
functionalizing a surface of the gate dielectric layer with linker molecules,
disposing an active channel comprising a network of separated nanotubes over the functionalized surface of the gate dielectric layer, wherein the network of separated nanotubes comprises separated semiconducting nanotubes, and
forming a source contact and a drain contact on two ends of the active channel with the network of separated nanotubes therebetween; and
coupling a capacitor to the transistors.

16. The method of claim 15, wherein the transistors comprise a first transistor and a second transistor, and coupling a capacitor to the transistors comprises:
coupling a first pin of a capacitor between the drain of the first transistor and the gate of the second transistor; and
coupling a second pin of the capacitor to the source contact of the second transistor.

17. The method of claim 16, further comprising coupling an organic light-emitting diode (OLED) display device to the drain contact of the second transistor.

18. The method of claim 15, further comprising depositing a SiO₂ layer on the gate dielectric layer to form a bilayer gate dielectric layer before functionalizing the surface of the gate dielectric layer.

19. The method of claim 15, wherein:
the transistors comprise a first transistor and a second transistor,
the gate of the first transistor is configured to receive a first voltage for controlling the first transistor,
the source of the first transistor is configured to receive a signal,
the drain of the first transistor is coupled to a gate of the second transistor,
the source or the drain of the second transistor is configured to receive a second voltage,
a current flowing across the second transistor is associated with the signal and the second voltage, and
the capacitor is configured to store and stabilize a voltage from the signal during a period.

20. The method of claim 19, further comprising an organic light-emitting diode display device coupled to the drain of the second transistor, and wherein an output light intensity of the organic light-emitting diode display device is modulated by the signal.
